(19) United States
(12) Patent Application Publication
(10) Pub. No.: US 2007/0124926 A1
(43) Pub. Date: Jun. 7, 2007

(54) CIRCUIT BOARD AND METHOD FOR MANUFACTURING THE SAME

(75) Inventors: Yukihiro Ishimaru, Osaka (JP); Seiichi Nakatani, Osaka (JP); Yoshiyuki Saito, Osaka (JP)

Correspondence Address: Hamre, Schumann, Mueller & Larson, P.C., P.O. Box 2902-0902, Minneapolis, MN, 55402, US

(73) Assignee: Matsushita Electric Industrial Co., Ltd., Osaka (JP)

(21) Appl. No.: 11/674,454

(22) Filed: Feb. 13, 2007

Related U.S. Application Data
(62) Division of application No. 11/075,578, filed on Mar. 8, 2005.

(30) Foreign Application Priority Data
Mar. 10, 2004 (JP) 2004-067845

(51) Int. Cl. H05K 1/03

(52) U.S. Cl. 29/830; 174/255; 174/262; 174/264; 29/846; 29/852

(57) ABSTRACT

In a circuit board according to the present invention, on a substrate, in at least a portion of a phase change layer including a phase change material that is capable of changing alternately between an electrically insulating state and an electrically conductive state, a conductive path is formed that has been put into an electrically conductive state by a phase change in the phase change layer, wherein the phase change material includes a chalcogenide semiconductor, changes between the electrically insulating state and the electrically conductive state by irradiation of laser light, goes into the electrically conductive state in a crystalline phase, and goes into the electrically insulating state in an amorphous phase. In this way, a conductive path is formed by irradiating laser light onto a phase change layer using phase change in a phase change layer formed from a phase change material that is capable of changing alternately between an electrically insulating state and an electrically conductive state, and therefore very small-dimension minute vias and conductors can be formed. Furthermore, subsequent repair, rework, or trimming also is easy.

### CROSS-REFERENCE TO RELATED APPLICATIONS

This application is a Division of application Ser. No. 11/075,578, filed Mar. 8, 2005, which application is incorporated herein by reference.

### BACKGROUND OF THE INVENTION

1. Field of the Invention

The present invention relates to circuit boards for the mounting of electronic components such as semiconductor devices for example, and to methods for manufacturing such circuit boards.

2. Description of the Related Art

Along with the miniaturization and increasingly high functionality of electronic equipment in recent years, there have been advances in increasing the number of pins in the semiconductor devices that constitute such electronic equipment and in miniaturization of such components, and the number and density of the wires of the printed boards on which these are mounted are increasing dramatically. In particular, the increasing minuteness of printed boards (circuit boards) is advancing due to the rapid increase in the number of leads drawn from these semiconductor devices and the number of terminals.

Today's most leading edge fine pitch level is a pitch in the range of 40 to 50 μm in the case of mounting semiconductor devices to FC (flip chips), and the dimensions of the vias and lands used as interlayer connection techniques at this time are respectively 50 μm and 100 μm. Furthermore, it is anticipated that a pitch of 20 μm in FC mounting and a pitch of 36 μm in BGA (ball grid array) mounting will be achieved by the year 2010.

In achieving wiring miniaturization techniques, it has been common to aim for thinner copper foils in the case of using etching and to use a semi-additive method or a full additive method in the case of using plating. Although there are issues such as high costs involved with wiring miniaturization techniques, technological issues basically have been overcome. Patent documents 1 to 7 listed below can be considered.

Although the technologies disclosed in patent documents 1 to 4 do not use a phase change material that is capable of changing alternately between an electrically insulating state and an electrically conductive state, a conductor portion of a wiring pattern is formed by changing a resistance value using laser irradiation. However, these technologies have the following problems.

Patent document 1 discloses a technique in which a predetermined area on an AlN (aluminum nitride) substrate surface is irradiated with a laser, thus reducing the resistivity in the laser irradiated portions of the AlN and thereby forming a conductor portion of a wiring pattern. With this technique, although it is indeed possible to form a wiring pattern with a laser, in addition to a high energy output laser (a highest output of 100 W with a Nd: YAG laser) being necessary, the material costs become higher than the costs of materials normally used for printed boards, and therefore manufacturing costs including installation costs and material costs become higher, and it would be extremely difficult to manufacture a product that could replace the printed boards being used today. Furthermore, this technique is one in which a wiring pattern is formed on a substrate surface and there is no mention in patent document 1 of forming vias with a laser. Further still, there also is the problem that the wiring here has a comparatively large resistance value. This is because, in wiring with a width of 100 μm and a length of 10 mm, the resistance value across the wiring would be approximately 1 ohm.

The below-mentioned patent documents 2 to 4 disclose techniques in which wiring is formed by irradiating an energy beam onto a diamond coat printed circuit board covered with a diamond thin film. In patent document 4, a technique also is shown in which vias made of graphite are formed by inducing phase change in diamond. However, compared to the printed boards that are widespread today, diamond coat printed circuit boards require a special manufacturing process to form the diamond thin film, which presents considerable problems in terms of manufacturing costs. Furthermore, since irradiation is carried out with an argon laser when carrying out laser irradiation, compared to laser irradiation with semiconductor lasers that have considerably smaller output than argon lasers, the laser irradiation process is a comparatively large-scale process. In addition to this, the resistance value of the (graphite) portions of formed wiring patterns that have changed to blackish due to laser irradiation is approximately 3 ohm/cm, so there is also the problem of a comparatively large resistance value. It should be noted that, as is well known, the phase change from diamond to graphite is irreversible and phase change from graphite to diamond does not occur.

Furthermore, patent documents 4 and 5 disclose a technique in which a conductor pattern is formed by carrying out ion irradiation on an electrically insulating surface. However, with this technique, obtaining electrical conductivity that can be used for wiring is difficult or complicated. This technique is one in which a conductor pattern is formed on a substrate surface and there is no mention in patent document 5 of forming vias with this technique. Further still, patent documents 6 and 7 disclose a molded or film formed composite material in which polymerization is caused by light irradiation and only the irradiated portions are changed to be conductive. However, it is difficult to obtain an electrical conductivity that can be used as wiring for a printed board with a material made of such a conductive polymer.

Patent Document 1: JP H1-173505 A

Patent Document 2: JP H3-268477 A

Patent Document 3: JP H5-175359 A

Patent Document 4: JP H5-36847 A

Patent Document 5: JP H2-184095 A

Patent Document 6: JP H3-297191 A

Patent Document 7: JP H7-188399 A

On the other hand, in interlayer connection technologies that use vias, there are not only merely cost-related issues in forming miniaturized vias above the current level, but also technological difficulties. This is because there is a limit to the miniaturization of via formation related to physical hole processing since either a technique is used in which vias are formed by plating after a drilling process or a technique is used in which vias are formed by plating after laser processing.

In other words, with hole processing based on drilling, at best only via holes of a size around 100 μm can be formed, and with hole processing that uses a CO₂ laser, it is possible to manage to form via holes of a size in the range of 30 to 50 μm. Although there are also techniques in which excimer lasers or the like are used, these are unlikely to be used in practice due to considerations of high cost. Furthermore, there is a limit due to aspect ratio when forming via holes using a photolithographic process, and when the aspect ration must be made, for example, two or lower, there will be a limit of 15 μm to the diameter of the via hole when the thickness of the electrically insulating layer is 30 μm.

Furthermore, if the holes (via holes) are to be made small, there is the problem that the smaller the holes become, the more difficult it is to fill the holes with a conductive material. When filling the holes with a conductive material using plating, considering the permeation conditions of the plating liquid, it is difficult to fill the holes well unless the aspect ratio is 2 or lower. Even when filling the holes with a conductive material using a conductive paste, holes with a diameter of at best 50 μm can be filled, and it is extremely difficult technologically to fill holes of 30 μm or smaller with the conductive material.

If reducing the surface area of circuit boards is desired as part of miniaturizing electronic devices, the limit dimension of via diameters becomes a bottleneck to design when the diameter of vias cannot be made more minute than current levels. In other words, being unable to form extremely minute vias easily has become an obstacle to miniaturizing circuit boards.

### SUMMARY OF THE INVENTION

In order to solve the above-described conventional problems, the present invention provides a circuit board in which very small vias and conductors can be formed and a method for manufacturing such a circuit board.

A circuit board according to the present invention is a circuit board, including:

a substrate, and

a phase change layer on the substrate, the phase change layer including a phase change material that includes a chalcogenide semiconductor and changes between an electrically insulating state in an amorphous phase and an electrically conductive state in a crystalline phase by irradiation of laser light,

wherein a conductive path is defined in the phase change layer by the phase change material in the electrically conductive state.

Note here that the phrase “on the substrate” as used herein should be interpreted broadly, and encompasses formation directly on a substrate or the presence of intervening materials.

A method for manufacturing a circuit board according to the present invention is a method for manufacturing a circuit board wherein, on a substrate, in at least a portion of a phase change layer including a phase change material that is capable of changing alternately between an electrically insulating state and an electrically conductive state, a conductive path is formed that has been put into an electrically conductive state by a phase change in the phase change layer,

wherein the phase change material includes a chalcogenide semiconductor, changes between the electrically insulating state and the electrically conductive state by irradiation of laser light, goes into the electrically conductive state in a crystalline phase, and goes into the electrically insulating state in an amorphous phase, the method including the steps of

(a) forming a phase change layer by depositing a phase change material that is capable of changing alternately between an electrically insulating state and an electrically conductive state; and

(b) forming in the phase change layer a conductive path including the phase change material by irradiating laser light on the phase change layer.

### BRIEF DESCRIPTION OF THE DRAWINGS

FIG. 1 is a cross-sectional view that schematically shows the configuration of a circuit board according to one embodiment of the present invention.

FIGS. 2A and 2B are diagrams for schematically describing the condition of phase transition in a chalcogenide semiconductor according to the same embodiment, with FIG. 2A showing an amorphous state and FIG. 2B showing a crystalline state.

FIGS. 3A and 3B are cross-sectional views for describing the step of forming a via and a conductor that extends in continuity from the via according to the same embodiment.

FIG. 4 is a cross-sectional view schematically showing the configuration of a circuit board according to the same embodiment on which a first phase change layer and a second phase change layer are formed.

FIGS. 5A to 5D are cross-sectional views for describing the steps of a method for manufacturing a circuit board according to a different embodiment of the present invention.

FIGS. 6A to 6C are cross-sectional views for describing the steps of a method for manufacturing a circuit board according to a different embodiment of the present invention.

FIGS. 7A to 7D are cross-sectional views for describing the steps of a method for manufacturing a circuit board according to a different embodiment of the present invention.

FIGS. 8A to 8C are cross-sectional views for describing the steps of a method for manufacturing a circuit board according to a different embodiment of the present invention.

FIGS. 9A to 9E are cross-sectional views for describing the steps of a method for manufacturing a circuit board according to a different embodiment of the present invention.

FIGS. 10A to 10D are cross-sectional views for describing the steps of a method for manufacturing a circuit board according to a different embodiment of the present invention.

FIGS. 11A to 11D are cross-sectional views for describing the steps of a method for manufacturing a circuit board according to a different embodiment of the present invention.

FIG. 12 is a top view for describing a method for manufacturing a circuit board according to a different embodiment of the present invention.

FIG. 13 is a perspective view for describing a method for manufacturing a circuit board according to a different embodiment of the present invention.

FIGS. 14A and 14B are cross-sectional views for describing the steps of a method for manufacturing a circuit board according to a different embodiment of the present invention.

FIG. 15 is a cross-sectional view schematically showing the configuration of a circuit board according to a different embodiment of the present invention.

FIGS. 16A and 16B are perspective views for describing the steps of a process of carrying out trimming according to a different embodiment of the present invention.

FIG. 17A is a cross-sectional view of a circuit board using phase change vias according to a different embodiment of the present invention, and FIG. 17B is a top view of the same.

FIG. 18A is a cross-sectional view of a circuit board using phase change vias according to a different embodiment of the present invention, and FIG. 18B is a top view of the same.

FIG. 19A is a cross-sectional view of a circuit board using phase change vias according to a different embodiment of the present invention, and FIG. 19B is a top view of the same.

FIGS. 20A to 20E are top views of a circuit board using phase change vias according to yet another different embodiment of the present invention.

FIG. 21A is a top view of a defect of a conductor according to a different embodiment of the present invention, and FIG. 21B is a top view showing repair of the defect.

FIGS. 22A to 22D are cross-sectional views of the steps of a different embodiment of the present invention.

FIG. 23A is a cross-sectional view showing a connection structure using a conventional plating method, and FIG. 23B is a top view of the same.

FIG. 24A is a cross-sectional view showing a connection structure using a conventional process that uses a conductive paste, and FIG. 24B is a top view of the same.

### DESCRIPTION OF THE PREFERRED EMBODIMENTS

With the present invention, a conductive path is formed by irradiating laser light onto a phase change layer using phase change in a phase change layer formed from a phase change material that is capable of changing alternately between an electrically insulating state and an electrically conductive state, and therefore very small-dimension minute vias and conductors can be formed. Furthermore, the phase change of a chalcogenide semiconductor according to the present invention is reversible, and therefore subsequent repair, rework, or trimming also is easy. As a result, production yields can be improved.

A circuit board according to the present invention can be used singly by itself and also can be used formed on a substrate. When used singly by itself, it is first constructed on a temporary substrate then transferred to a final substrate.

In a preferred embodiment of the present invention, the conductive path is at least one of a via and a conductor, and the phase change material is a material that changes between an electrically insulating state and a electrically conductive state due to irradiation of laser light, and the conductive path is made from the phase change material in the electrically conductive state.

The phase change material is a material that undergoes phase transition between a crystalline phase and an amorphous phase. The phase change material is a chalcogenide semiconductor.

In a preferred embodiment of the present invention, a via is formed as the conductive path in the phase change layer, and a conductor made of metal is connected to the via at a surface of the phase change layer.

In a preferred embodiment of the present invention, a via is formed as the conductive path in the phase change layer, and a conductor made of the phase change material also is formed at the phase change layer.

In a preferred embodiment of the present invention, the conductor is connected to the via.

In a preferred embodiment of the present invention, a plurality of vias are formed as the conductive path, and at least one of the plurality of vias is formed at an inclination from a normal line direction of the circuit board.

In a preferred embodiment of the present invention, a base substrate on which a conductor layer is formed on at least its surface further is provided as a base substrate of the phase change layer.

In a preferred embodiment of the present invention, a further phase change layer is formed on the phase change layer, and a conductive path is formed also in the further phase change layer and is made of the phase change material.

In a method for manufacturing a circuit board of the present invention, the laser light in the step (b) preferably is irradiated with a semiconductor laser.

The laser light in the step (b) preferably is irradiated in a state in which the phase change layer is rotatable.

In a preferred embodiment, in the step (b), a conductor is formed as the conductive path in a surface of the phase change layer and a via is formed as the conductive path extending from a portion of the conductor.

A method for manufacturing the circuit board of the present invention further may include, a step of forming a third phase change layer made of the phase change material on the second phase change layer, a step of forming a via made of the phase change material in the third phase change layer by irradiating laser light from a semiconductor laser to the third phase change layer, a step of forming a fourth phase change layer made of the phase change material on the third phase change layer, and a step of forming a conductor made of the phase change material in the fourth phase change material by irradiating laser light from the semiconductor laser to the fourth phase change layer.

In the method for manufacturing the circuit board of the present invention, the step of forming the second phase change layer may include a step of depositing a phase change material onto the first phase change layer so as to cover the conductor made of metal and a step of flattening the deposited phase change material.

The present invention provides a circuit board on which very small dimension vias can be formed. As mentioned above, although it is possible with conventional techniques to form a via with a diameter of approximately 100 μm using a drill, or a via at best in an approximate range of 30 to 50 μm using a C0₂ laser, it is quite difficult technologically to form vias with smaller dimensions than that.

In these circumstances, the inventors examined the forming of vias by a different approach than conventional techniques, thus leading to the present invention. This is not a technique of forming a hole on a board and then filling that hole with a conductive material, but rather a technique in which, without forming a hole, a via is formed by irradiating with a semiconductor laser a phase change layer made of a phase change material that is capable of changing alternately between an electrically insulating state and an electrically conductive state. By using such a method, it became evident that it is possible for form minute vias with a diameter of approximately 1 μm for example.

The phase change material in which the vias are formed is made from a material in which a resistance value is changed by a phase transition (a phase transition between a crystalline phase and an amorphous phase), and it is possible to cause a change from the electrically insulating state (amorphous phase) to the electrically conductive state (crystalline phase) by the irradiation of laser light. Vias are configured by the phase change material in the electrically conductive state. For the phase change material, it is possible to use a chalcogenide semiconductor that is capable of phase transition between a crystalline phase and an amorphous phase.

The electrical conductivity of a chalcogenide semiconductor can be made to have an approximately four or five orders of magnitude of difference between the crystalline phase and the amorphous phase at room temperature and, moreover, since it is possible to maintain the crystalline phase and the amorphous phase stably with a chalcogenide semiconductor at room temperature, it is possible to form electrically insulating portions and electrically conductive portions (vias and the like) by phase change between the electrically insulating state and the electrically conductive state.

A method for forming conductive paths (vias, conductors, and the like) according to the present invention is effective, since it is possible to form conductive paths by carrying out irradiation with a semiconductor laser on a phase change material that is capable of changing alternately between an electrically insulating state and an electrically conductive state. It also is possible to form minute vias precisely with good efficiency, because it is not necessary to form holes by drill processing or laser processing and then to fill these holes with a conductive material.

It is preferable that the thickness of the phase change material layer is in the range of 0.5 to 20 μm and more preferably in the range of 1 to 10 μm. The phase change material layer can be formed by a method such as spin coating, vacuum deposition, and sputtering. Furthermore, a protective layer may be provided on the phase change material. A dielectric material of a thickness in the range of 10 to 100 nm can be used for the protective layer. For example, ZnS—SiO₂ can be used for the dielectric material.

The present invention can be applied to various uses such as flexible printed boards, double-sided substrates, and multilayer boards.

The following are descriptions of embodiments of the present invention with reference to the accompanying drawings. The present invention is not limited to the following embodiments. In order to simplify description, in the following drawings, structural elements having a substantially same function are indicated with the same reference numerals.

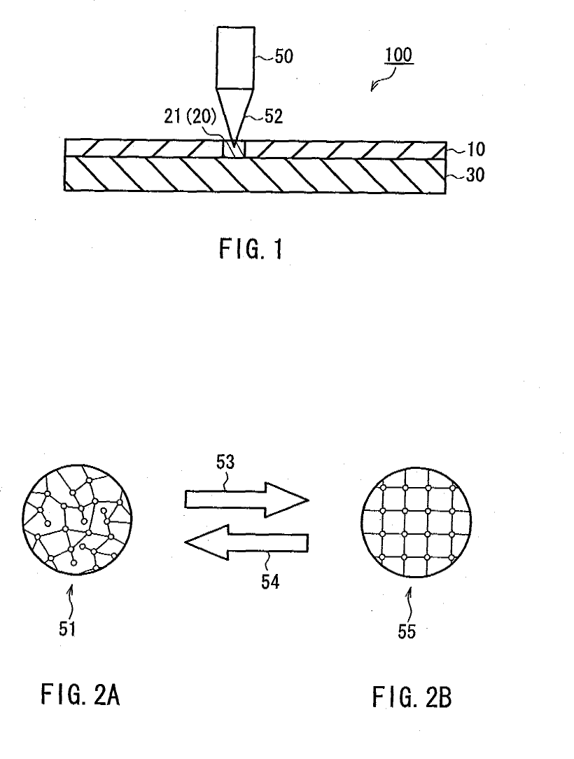

The following is a description of a circuit board according to an embodiment of the present invention with reference to FIGS. 1 and 2. FIG. 1 is a cross-sectional view that schematically shows the configuration of a circuit board 100 according to the present embodiment.

The circuit board 100 shown in FIG. 1 is constituted by a phase change layer 10 and a conductive path 20 formed on the phase change layer 10. The phase change layer 10 is made of a phase change material that is capable of changing alternately between an electrically insulating state and an electrically conductive state, The conductive path 20 in the example shown in FIG. 1 is a via 21 and the via 21 is constituted by a phase change material. This phase change material is a material with which a phase transition between a crystalline phase and an amorphous phase is carried out, and the phase transition is brought about, for example, by light (laser light), heat, electrical pulses, or the like.

The phase change material that constitutes the phase change layer 10 and the conductive path 20 (via 21) is a material that changes between an electrically conductive state and an electrically conductive state at least by irradiation of laser light. In the example shown in FIG. 1, the conductive path 20 (via 21) is in a crystalline state of high electrical conductivity, and regions of the phase change layer 10 other than that are in an amorphous state of an electrical conductivity lower than that of the conductive path 20. The difference in electrical conductivity between the conductive path 20 and the phase change layer 10 other than that preferably is a factor of at least 10⁴, for example, or more preferably at least 10⁵.

The value of electrical resistance of the conductive path preferably is in the range of 10¹ to 10⁴ S/cm.

In the present embodiment, the conductive path 20 (via 21) is formed, as shown in FIG. 1, by causing a phase transition of the phase change material with irradiation of laser light 52 of a semiconductor laser 50. Output of the semiconductor laser 50 is considerably lower compared to output of a solid state laser (for example, a YAG laser) or a gas laser (for example, a CO₂ laser) used in applications of hole opening processes, and therefore the semiconductor laser 50 may be called a low output laser. In contrast to the output of a YAG laser, which is 500 W for example, or the output of a CO₂ laser, which is 200 W for example, the output of a semiconductor laser 50 may be at most 100 mW for example (in the range of 50 to 80 mW in some examples). A GaAs based, InGa—AsP based, or a GaN based semiconductor laser can be used for the semiconductor laser 50.

In the present embodiment, a chalcogenide semiconductor is used for the phase change material. The chalcogenide semiconductor is an alloy that includes at least one chalcogen element (namely a group six element) as an essential element. It is possible to use a chalcogenide semiconductor of different characteristics depending on the mixing proportions or the constitute elements therein. The chalcogenide semiconductor of the present embodiment includes a chalcogen element (S, Se, Te) that is a principal constituent, and a pnicogen element (such as As and Sb) that is a secondary constituent. A preferable abundance ratio of the principal constituent to the secondary constituent is one in which the element ratio of chalcogen element to pnicogen element is in the range of 1:0.1 to 1:1.

The principal constituent of the former is two-coordinated and the secondary constituent of the latter is three-coordinated, forming a two-dimensional covalent network structure. In this way it is possible to induce phase change easily. That is, with chalcogenide semiconductors, the bonding has a chain structure, and therefore the structure becomes flexible and rearrangement of the structure occurs easily. As a result both the crystalline state and the amorphous state can be maintained. It should be noted that the networks are bonded with Van der Waals force, and are therefore structurally flexible compared to an amorphous semiconductor constituted entirely by covalent bonds. Amorphous chalcogenide is also called chalcogenide glass (chalcogen compound glass).

With Te—Ge—Sn—Au based and Sn—Te—Se based chalcogenide semiconductors, it is possible to induce amorphous-crystalline phase changes using light irradiation. Furthermore, with Te—As—Ge—Si based semiconductors, it is possible to induce an amorphous-crystalline phase change using heat generated by an electric current for example. Other examples include Ce—Sb—Te based semiconductors and Te based semiconductors with As and Sb added. Other additional examples of alloys in which phase change can be induced include: GaSb, InSb, InSe, Sb₂Te₃, and GeTe as two-component based alloys, Ge₂Sb₂Te₅, InSbTe, GaSeTe, SnSb₂Te₄, and InSbGe as three-component based alloys, and AgInSbTe, (GeSn)SbTe, GeSb(SeTe), and Te₈₁Ge₁₅Sb₂S₂ as four-component based alloys, FIGS. 2A and 2B are schematic drawings for describing the condition of phase transition in the chalcogenide semiconductor. Atomic rearrangement is induced (see arrow 53) with a crystaliization temperature by applying Joule heat for example such that a low-conductive amorphous state 51 (FIG. 2A) changes to a high-conductive crystalline state 55 (FIG. 2B). On the other hand, when the temperature is raised above melting point to melt the crystals and then, immediately after, the temperature is lowered rapidly, the high-conductive crystalline state 55 (FIG. 2B) changes to the low-conductive amorphous state 51 (FIG. 2A) via a supercooled liquid state (see arrow 54) due to the rapid temperature gradient.

The phase change layer 10 made of a phase change material is formed on a base substrate 30. The base substrate 30 is a substrate on which a conductor layer is formed on at least the surface. In the present embodiment, a portion (for example, a land) of the conductor layer of the base substrate 30 is positioned at an area of a bottom surface of the via 21. The base substrate 30 may be, for example, a rigid board (a typical printed board) and a single sided or a double sided rigid board may be used in the present embodiment. It should be noted that in FIG. 1, only a single via 21 is shown, but a plurality of vias 21 may be formed.

With the circuit board 100 of the present embodiment, the via 21 is formed by irradiating laser light 52 on the phase change layer 10, and therefore the dimension of the via 21 (its diameter for example) can be made small. That is, it is possible to achieve a circuit board having via dimensions that have been difficult to achieve when forming vias by forming holes with drill processing or laser processing and then filling these holes with a conductive material.

There is no particular problem in making the dimension (diameter) of the via 21 in the range of 100 μm to 30 μm or larger than that for example, but the comparatively smaller size has a large technological significance. When the shape of the via 21 is substantially round, the diameter of the via 21 may be at most 10 μm for example, and when a small via diameter is desired, the diameter may be at most 1 μm for example (in the range of 0.1 to 0.5 μm as one example).

Being able to make a small via dimension allows leeway in the precision of uniformity of the lands that connect to the vias. As a result, limitations in circuit board design are eased and it is also possible to achieve the effect of making it easier to estimate error (tolerance) at the manufacturing stage. That is to say, when the precision of uniformity between the vias and lands is ±25 μm, a land dimension (the diameter for example) is required to be at least 100 μm if attempting to form vias with a via diameter of 50 μm with typical manufacturing methods. On the other hand, when forming vias with a via diameter of 10 μm using a structure of the present embodiment, it is sufficient for the land dimension (the diameter for example) to be 60 μm, and therefore the level of design freedom can be increased by the proportion by which the lands can be made small. Furthermore, this proportion offers leeway in the precision of uniformity when keeping the land dimension as it is at 100 μm, such that it becomes easier to execute manufacturing processes and it becomes possible to improve yields.

Further still, it is possible to use the semiconductor laser 50 as the irradiation source of the laser light 52, and therefore it is also possible to achieve the effect of being able to keep equipment costs down. Compared to using a high output laser device (a CO₂ laser for example) as the irradiation source of the laser light 52, it is possible to reduce the involved equipment costs to one-hundredth or less when using the semiconductor laser 50. Furthermore, the semiconductor laser 50 also is easy to handle and in that sense too it has great merit in manufacturing processes.

Additionally, since the conductive path 20 is made of a phase change material that is capable of changing alternately between the electrically insulating state and the electrically conductive state, even after being formed once, it has the special property of being able to be erased again through a specific process. That is, even after being phase changed from the amorphous state (reference numeral “51” in FIG. 2) to the crystalline state (reference numeral “55” in FIG. 2), the chalcogenide semiconductor that forms the conductive path 20 can be made to change phase again from the crystalline state (reference numeral “55” in FIG. 2) to the amorphous state (reference numeral “51” in FIG. 2), and therefore it is possible to erase the conductive path 20 that has once been formed. In this way, even when the conductive path 20 is formed in a mistaken position, it is possible to erase it and then form the conductive path 20 again in the correct position.

When manufacturing the circuit board 100 of the present embodiment, first the phase change layer 10 made of a phase change material in an amorphous state may be formed by depositing the phase change material on the base substrate 30, after which the via 21 (conductive path 20) made of the phase change material in a crystalline state may be formed by irradiating the laser light 52 on the phase change layer 10. The dimension (diameter) of the via 21 can be regulated by the beam diameter of the laser. There is no particular limitation to the thickness of the phase change layer 10, but it was set in the range of 5 to 30 μm in the present embodiment. When an upper surface and a lower surface of the via 21 are respectively exposed at an upper surface and a lower surface of the phase change layer 10, the thickness of the phase change layer 10 is the height of the via 21.

In the structure shown in FIG. 1, it is possible to form a metal conductor that connects to the via 21 at the surface of the phase change layer 10. Furthermore, in the phase change layer 10, apart from the via 21, it is also possible to form a conductor (conductive path) made of phase change material.

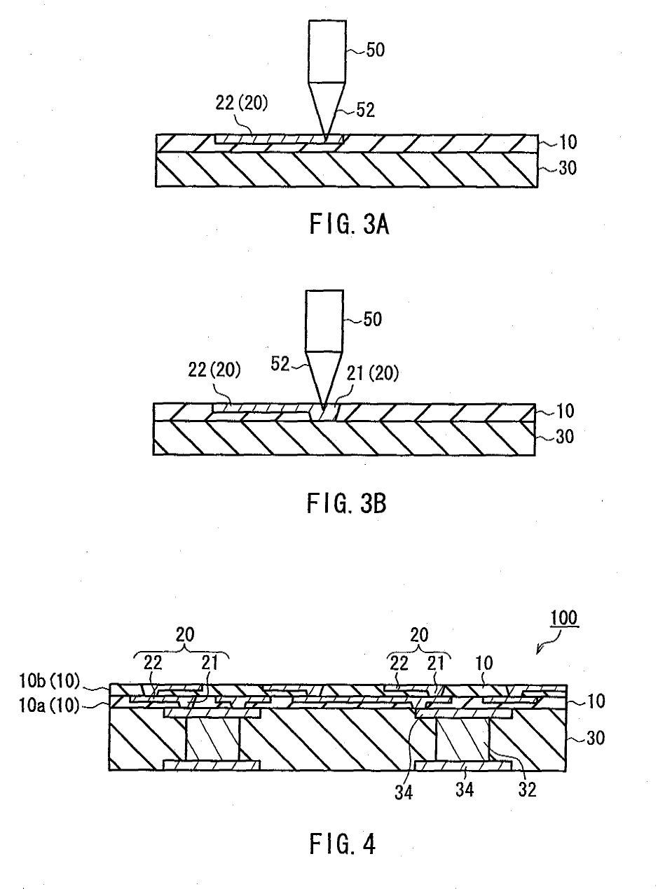

Further still, in the phase change layer 10, it is also possible to form the via 21 and a conductor that extends in continuity with the via 21. This will be described with reference to FIGS. 3A and 3B.

Firstly, as shown in FIG, 3A, a conductor 22 (the conductive path 20) is formed on the surface of the phase change layer 10 by moving the laser light 52 on the phase change layer 10 on the base substrate 30. The conductor 22 is made of phase change material. The width of the conductor 22 can be regulated by the beam diameter of the laser light 52, and the path of the conductor 22 can be regulated by controlling the movement of the laser light 52.

Next, as shown in FIG. 3B, when the laser light 52 reaches the area desired for forming the via 21, the movement of the semiconductor laser 50 is stopped there, and the via 21 is formed in the phase change layer 10 by stationary irradiation of the laser light 52. In this way it is possible to achieve a conductive path 20 in which the conductor 22 and the via 21 are a single entity. It should be noted that the position of the via 21 is not limited to the end portion of the conductor 22 and may be a central portion, and it is possible to form the conductor 22 that extends in continuity with the via 21 after forming the via 21.

With this structure, there is no joint between the conductor 22 and the via 21, and therefore there is the advantage of superior connection reliability between the conductor 22 and the via 21. That is, in the case of an ordinary via connection, the via portion (conductive paste or plating) and the land portion that is formed on the via portion are connected by being brought into contact, and therefore reliability decreases when the substrate thermally expands in the thickness direction. On the other hand, with the structure shown in FIG. 3B, the via 21 and the conductor 22 are formed to be linked as a single entity, and therefore there is no connection site and there is superior connection reliability.

Furthermore, since the conductor 22 and the via 21 are formed from a phase change material from the start, similarly to the phase change layer 10, the coefficient of thermal expansion of the conductor 22 and the via 21 is the same or extremely close to the coefficient of thermal expansion of the phase change layer 10. Accordingly, there is superior reliability in that sense too. Additionally, since the conductor 22 and the via 21 are formed in continuity with the same material with no joint, it is also possible to avoid the problem of mismatched impedance between the vias and the lines.

The circuit board 100 of the present embodiment also can be a multilayer structure. FIG. 4 shows a circuit board 100 in which a first phase change layer 10a and a second phase change layer 10b are formed on the base substrate 30.

Conductive paths 20 (21 and 22) are formed in the first phase change layer 10a and conductive paths 20 (21 and 22) also are formed in the second phase change layer 10b. In the example shown in FIG. 4, the bottom surface of the via 21 formed in the second phase change layer 10b is in contact with the conductive paths 20 (21 and 22) formed in the first phase change layer 10a. Furthermore, a via 32 made of metal and a land 34 positioned at an upper surface and lower surface of the via 32 are formed in the base substrate 30 shown in FIG. 4. The land 34 may be a portion of a metal conductor. The via 21 formed in the first phase change layer 10a is electrically connected to the land 34 of the base substrate 30.

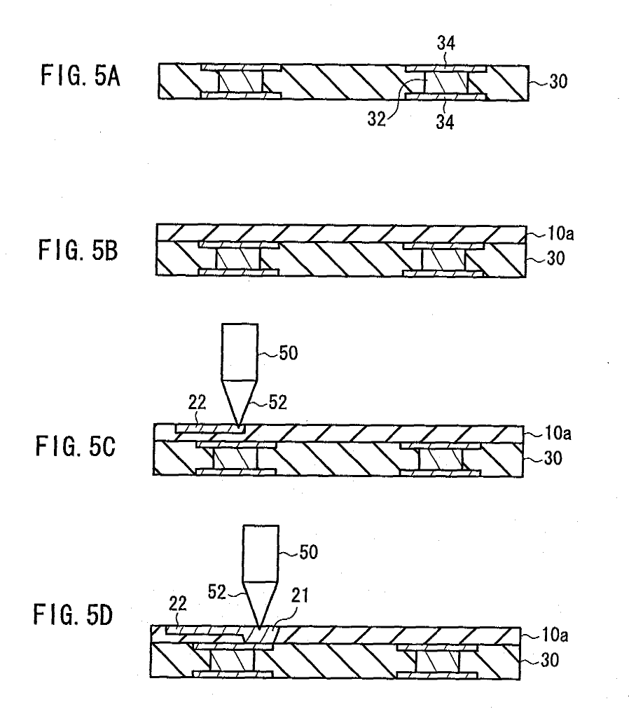

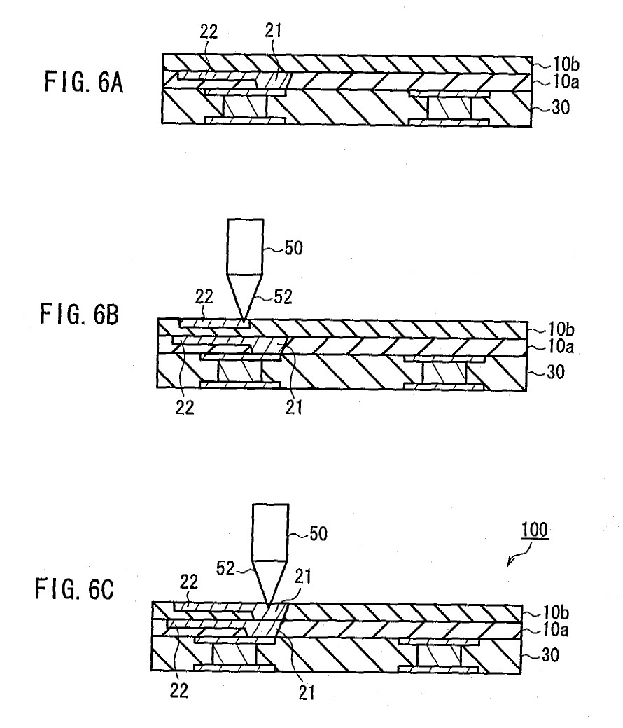

Next, a method for manufacturing the circuit board 100 of the present embodiment having a multilayer structure will be described with reference to FIGS. 5A to 6C.

Firstly, after preparing the base substrate 30 as shown in FIG. 5A, the first phase change layer 10a is formed at the surface of the base substrate 30 as shown in FIG. 5B. The first phase change layer 10a may be formed by depositing the phase change material by vacuum deposition or sputtering. The first phase change layer 10a may be made from a chalcogenide semiconductor in an amorphous state and is initially in an electrically insulating state.

Next, by irradiating laser light 52 from the semiconductor laser 50 as shown in FIG. 5C, the conductor 22 is formed in the first phase change layer 110a. Following this, as shown in FIG. 5D, the via 21 is formed in continuity with the conductor 22 in a predetermined location of the first phase change layer 10a.

Next, as shown in FIG. 6A, the second phase change layer 10b is laminated onto the first phase change layer 10a in which the conductor 22 and the via 21 are formed. Following this, as shown in FIG. 6B, the conductor 22 is formed in the second phase change layer 10b by the laser light 52 from the semiconductor laser 50. After this, the conductor 22 of the first phase change layer 10a and the conductor 22 of the second phase change layer 10b are electrically connected by forming the via 21 in the second phase change layer 10b as shown in FIG. 6C, thus producing the circuit board 100 of the present embodiment having a multilayer structure.

It should be noted that it is possible to produce a circuit board 100 having a three-layer structure or a multilayer structure greater than that by further carrying out the same process.

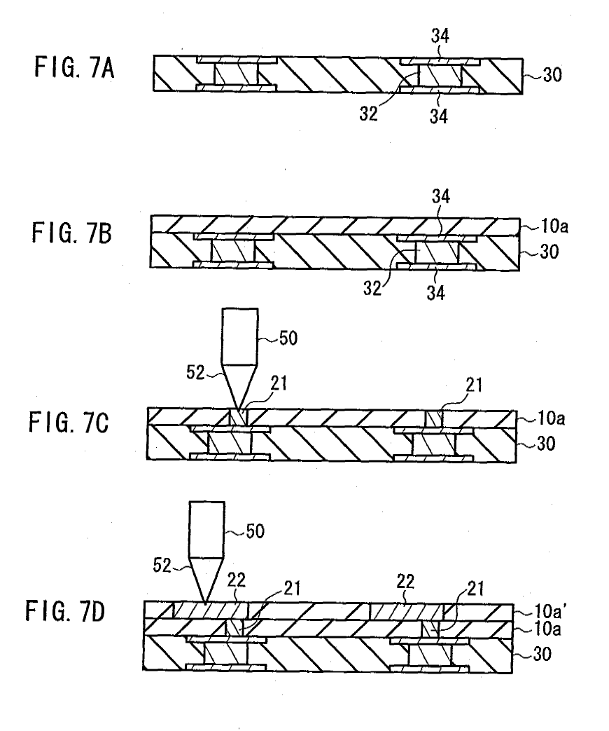

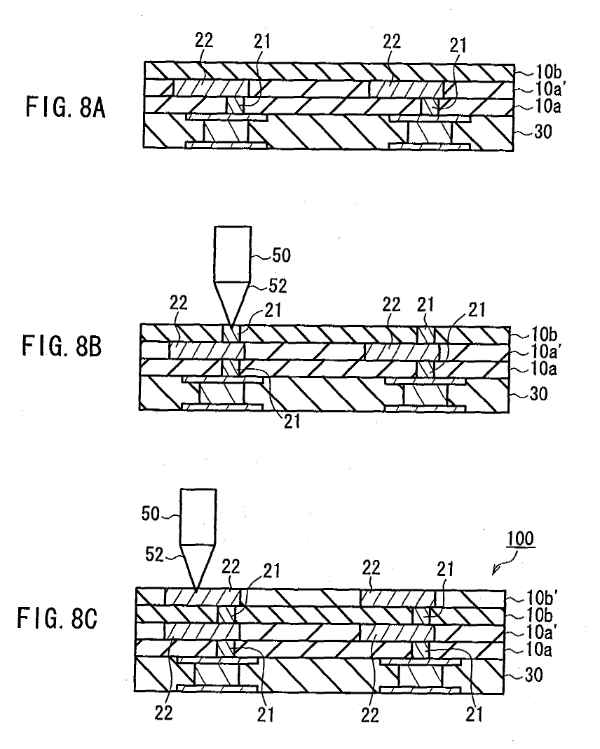

Further still, the circuit board 100 of the present embodiment also can be produced as shown in FIGS. 7A to 8C.

Firstly, after preparing the base substrate 30 as shown in FIG. 7A, the first phase change layer 10a is formed on the base substrate 30 as shown in FIG. 7B. Next, as shown in FIG. 7C, the via 21 is formed by irradiating the laser light 52 on the first phase change layer 10a. After this, as shown in FIG. 7D, another layer of first phase change layer 10a′ is formed on the first phase change layer 10a in which the via 21 is formed, and after this, a portion of the conductor 22 and the via 21 are connected by forming the conductor 22 in the first phase change layer 10a′.

Next, as shown in FIG. 8A, the second phase change layer 10b is formed on the first phase change layer 10a′ in which the conductor 22 is formed. Following this, as shown in FIG. 8B, the via 21 is formed in the second phase change layer 10b. After this, as shown in FIG. 5C, another layer of second phase change layer 10b′ is formed on the second phase change layer 10b in which the via 21 is formed, and after this, a portion of the conductor 22 of the second phase change layer 10b′ and the via 21 of the second phase change layer 10b are connected by forming the conductor 22 in the second phase change layer 10b′.

In this way, the circuit board 100 of the present embodiment can be produced. It is possible to produce a circuit board 100 having a multilayer structure of three or more layers by repeating the same process. With the manufacturing method shown in FIGS. 7A to 8C, the vias 21 and the lines 22 can be produced independently, and therefore there is the advantage that the thicknesses of the vias and the lines can be controlled easily. On the other hand, with the manufacturing method shown in FIGS. 5A to 6C, it is possible to form these at one time, and therefore there is the advantage of superior productivity. It should be noted that it is also possible to use the manufacturing method shown in FIGS. 5A to 6C and the manufacturing method shown in FIGS. 7A to 8C in combination.

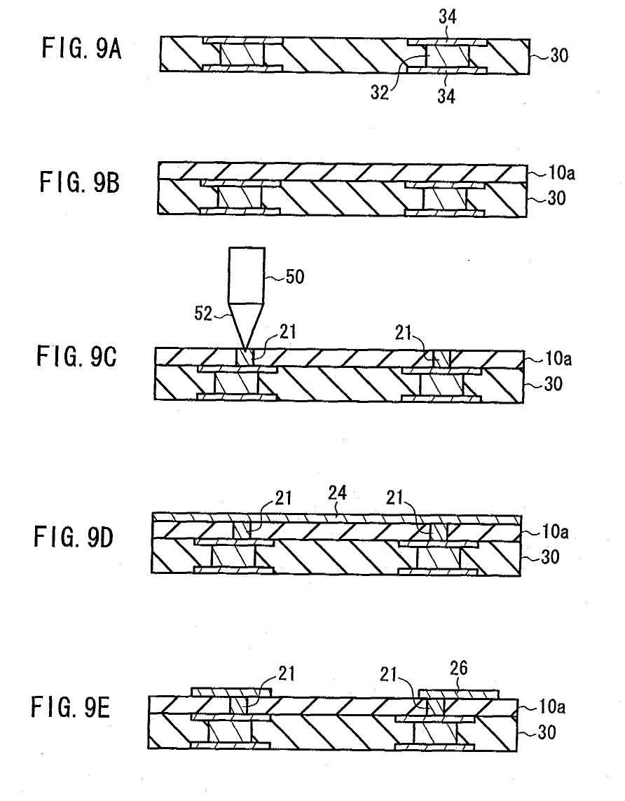

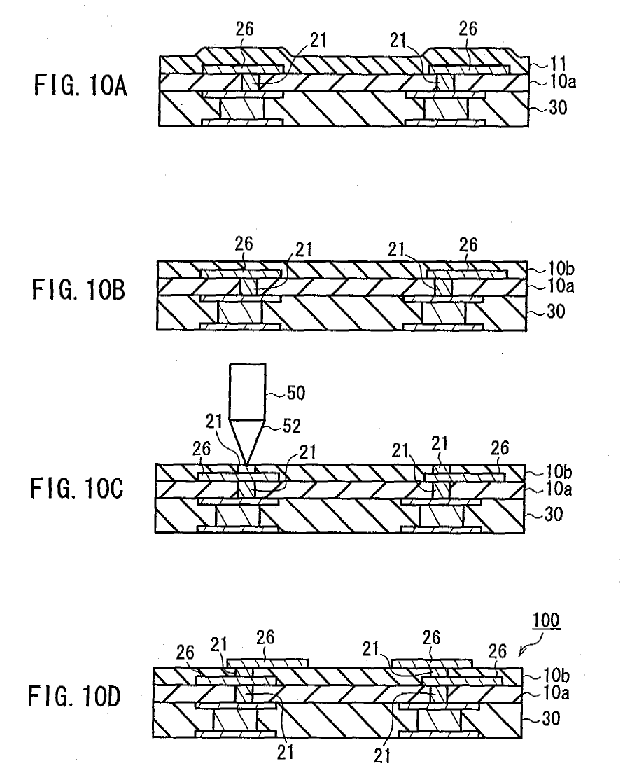

Furthermore, it is also possible to form only the vias 21 from the phase change material and to form the conductors from a metal material. This manufacturing method will be described with reference to FIGS. 9A to 10D.

Firstly, after preparing the base substrate 30 as shown in FIG. 9A, the first phase change layer 10a is formed on the base substrate 30 as shown in FIG. 9B, then the vias 21 are formed with the laser light 52 in the first phase change layer 10a as shown in FIG. 9C.

Next, as shown in FIG. 9D, a metal layer 24 is formed on the first phase change layer 10a in which the vias 21 are formed. Following this, patterning is carried out on the metal layer 24 to form the metal conductor 26 as shown in FIG. 9E. The formation of the metal layer 24 can be carried out by a plating method for example. Furthernore, the formation of the metal conductor 26 can be carried out by a photolithographic method for example.

Next, as shown in FIG. 10A, a phase change material 11 is deposited on the first phase change layer 10a so as to cover the metal conductors 26, after which the surface of the deposited phase change material 11 is flattened to form the second phase change layer 10b as shown in FIG. 10B. The flattening process may be carried out by polishing for example.

Next, as shown in FIG. 10C, the vias 21 are formed in the second phase change layer 10b with the laser light 52. After this, as shown in FIG. 10D, when the metal conductors 26 are formed on the second phase change layer 10b in which the vias 21 are formed, it is possible to achieve the circuit board 100 of the present embodiment having a multilayer structure of two or more layers. As shown in FIGS. 9D and 9E, the formation of the metal conductors 26 can be carried out by performing patterning after the metal layer 24 has been deposited.

With the circuit board 100 obtained by this manufacturing method, the metal conductor (copper conductor for example) 26 is used for the wiring, and therefore can be made to have a lower resistance than the conductor 22 made of phase change material. Furthermore, there is the advantage of superior solderability for connecting components on the conductors 26 with soldering.

It should be noted that, as shown in FIGS. 9E and 10D, all the conductors may be made of metal, but a portion (for example, an upper portion) of the conductors that are made of phase change material can be formed from metal so as to reduce the resistance value and increase the electrical conductivity.

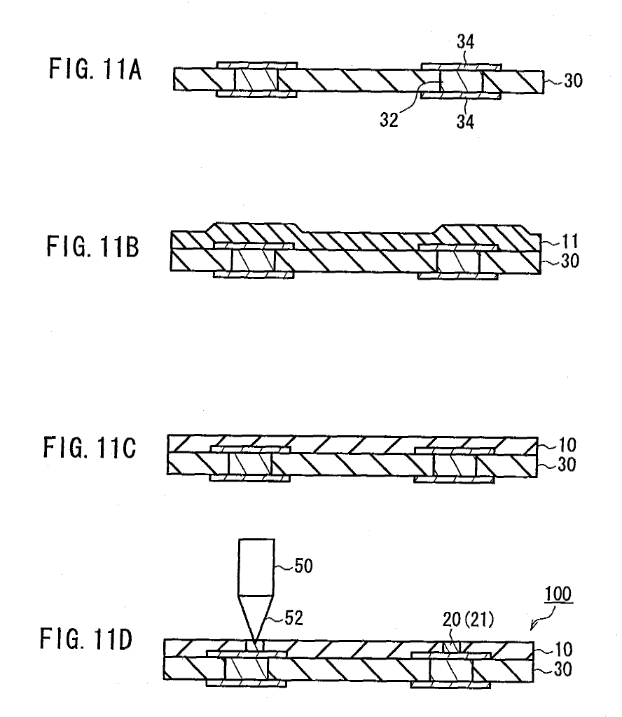

Furthermore, the flattening process shown in FIGS. 10A and 10B can be carried out not only when manufacturing a circuit board 100 of a multilayer structure but also when manufacturing a circuit board 100 of a single layer structure. For example, as shown in FIG. 11A, when a land (or a portion of a conductor) 34 of the base substrate 30 protrudes from the surface of the base substrate 30, it is common that the surface of the phase change material 11 is not flat as shown in FIG. 11B when the phase change material 11 is deposited on the base substrate 30.

At such times, by carrying out a flattening process, the surface of the phase change material 11 can be flattened as shown in FIG. 11C so that the phase change layer 10 can be obtained. After this, as shown in FIG. 11D, the conductive path 20 (via 21) may be formed in the phase change layer 10. In the structure shown in FIG. 11D, a further metal conductor may be formed on the phase change layer 10, and it is also possible to form a new phase change layer (a second phase change layer).

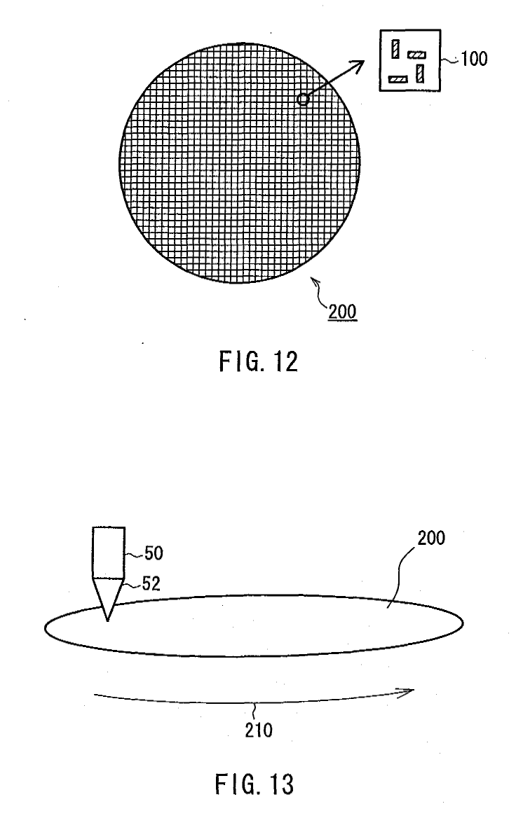

In manufacturing a circuit board 100 of the present embodiment, it is possible to carry out the forming of the conductive paths 20 (21 and 22) using the irradiation of the laser light 52 under a condition in which the phase change layer 10 is rotatable. For example, as shown in FIG. 12, this is possible by providing a wafer 200 by arranging substrates (or the base substrates 30) that have a phase change layer and will later form the circuit boards 100, and, as shown in FIG, 13, setting the wafer 200 in a rotatable condition. The conductive paths 20 (21 and 22) are formed on the phase change layer 10 on the wafer 200 by the writing of the laser light 52 irradiated from the semiconductor laser 50. There is no limitation to a single semiconductor laser 50 and a plurality of these may be provided.

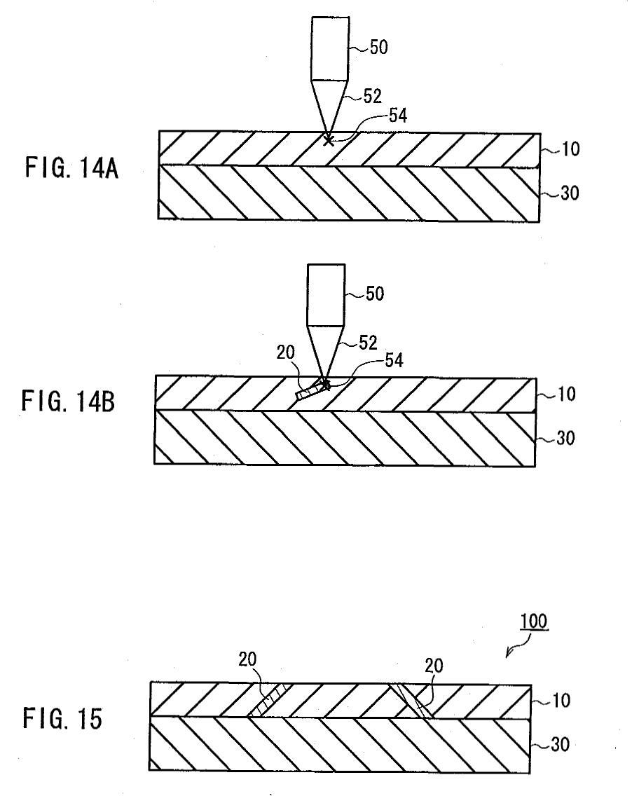

When using the configuration shown in FIGS. 12 and 13, in addition to being able to move the relative position of the laser light 52 by rotation (see arrow 210) of the wafer 200, it is also possible to adjust the temperature of the phase change layer 10 by the rotation rate of the wafer 200. As mentioned above, since phase change in the phase change layer 10 is affected by temperature, there is large merit in being able to carry out temperature control using the rotation rate of the wafer 200.

The conductive paths 20 of the present embodiment are formed with the laser light 52, and therefore, unlike paths obtained by typical formation methods of vias and conductors, there is comparative freedom in selecting paths (for example, three-dimensional inclinations).

For example, as shown in FIG. 14A, it is possible to adjust a focal point 54 of the laser light 52 on a center of the phase change layer 10 and make that a starting point of the conductive path 20. And, as shown in FIG. 14B, it is possible to form the conductive path 20 with a path inclined from the normal line direction of the base substrate 30 by diagonally moving (in this example, moving upwards diagonally) the focal point 54 of the laser light 52. The focal point 54 of the laser light 52 may be aligned with a position of a bottom surface of the phase change layer 10. Or, the focal point 54 of the laser light 52 may be aligned first on the surface of the phase change layer 10 and then the focal point 54 can be moved downwards diagonally, FIG. 15 shows a circuit board 100 in which a plurality of diagonally slanted conductive paths 20 are formed in the phase change layer 10.

By using the conductive paths 20 shown in FIGS. 14B and 15, it is possible to connect terminal to terminal with the shortest distance, a result of which is that there is also a separate effect of being able to shorten conductor lengths. Although the conductive paths 20 can be categorized as being close to vias, functionally they have both the function of a via and the function of a conductor.

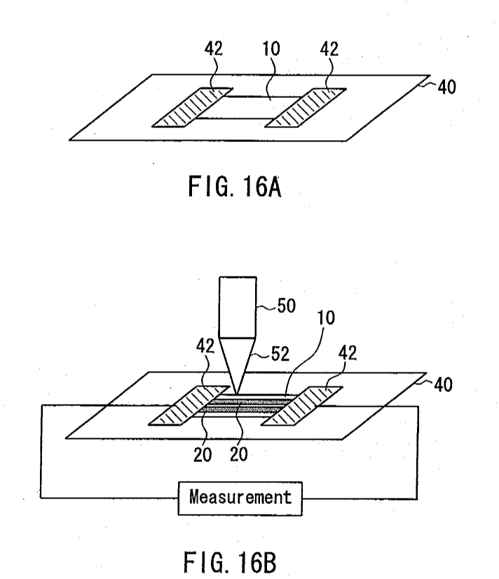

Further still, the conductive paths 20 of the present embodiment are applicable also to trimming technologies. “Trimming technologies” generally refers to technologies by which circuits or their elements are configured such that the manufacturing deviance of the entire circuitry can be corrected by fine adjustments of a small number of resistors, and then adjusting their resistance values after manufacture to achieve high-precision circuits. Laser trimming methods generally are used for trimming and carried out, for example, by partially removing printed electric components using an expensive high output laser device. On the other hand, by using the configuration of the present embodiment, trimming can be carried out easily and accurately without using a large-scale laser trimming method. This will be described with reference to FIGS. 16A and 16B.

Firstly, as shown in FIG. 16A, the phase change layer 10 is formed on a portion of a circuit board 40 on which predetermined circuitry (not shown in drawings) is formed. The phase change layer 10 is formed between terminals 42. Then, as shown in FIG. 16B, while measuring an electric characteristic between the terminals 42, conductive paths (conductors) 20 are formed at the phase change layer 10 by irradiating the laser light 52 using the semiconductor laser 50. In order to obtain a desired electric characteristic, the resistance value between the terminals 42 is adjusted and trimming is completed. Carrying out trimming with this method is extremely useful since an expensive high powered laser device is not necessary and trimming can be carried out easily.

Further still, along with the development in recent years of small-size, high-density mounting technologies of electronic devices represented by mobile telecommunications devices and notebook computers, circuit boards applicable to SMT (surface mount technology) have become increasingly widespread, and there is a tendency for a greater number of complex circuit components to be used in which trimming is essential, such as the VCO (voltage controlled oscillators) and TCXO (temperature compensated crystal oscillators) mounted in these. Therefore the trimming used for the configuration of the present embodiment has a large technological significance.

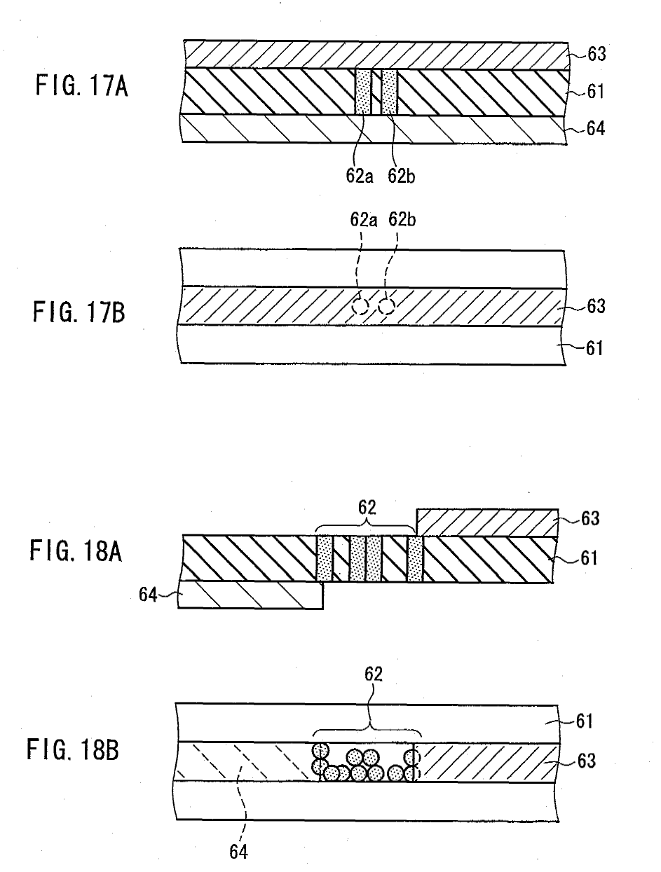

FIG. 17A is a cross-sectional view of a circuit board using phase change vias in a different embodiment of the present invention, and FIG. 17B is a top view of the same. Vias 62a and 62b, which are in an electrically conductive state, are formed in the thickness direction of a phase change material layer 61, which is in an electrically insulating state, and conductor layers 63 and 64 are formed on respective sides of the phase change material layer 61. Land portions are not particularly necessary and electrical connection of the vias can be achieved with the conductors only.

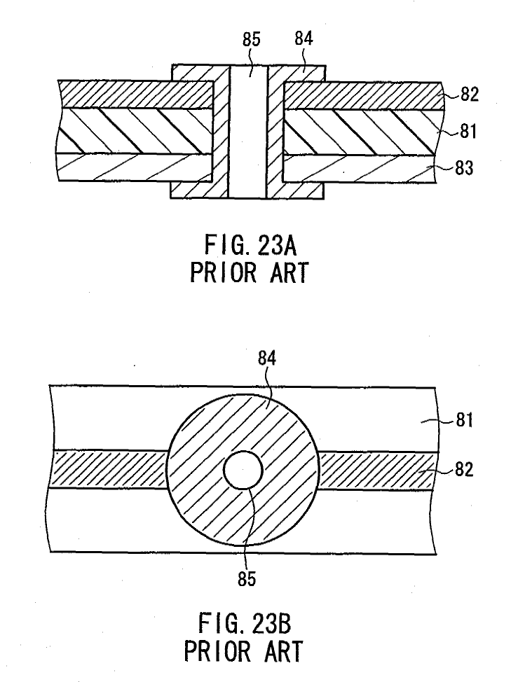

For comparison, a connection structure using a conventional plating method is shown in FIG. 23A (cross-sectional view) and FIG. 23B (top view). Conductors 82 and 83 are formed by etching on respective sides of a substrate 81, a through hole 85 is opened in the thickness direction, a via is formed in the thickness direction by plating, and a land 84 is formed. For this reason, it is necessary to use extra space for the surface area portion of the land, and it is difficult to make the entire structure compact.

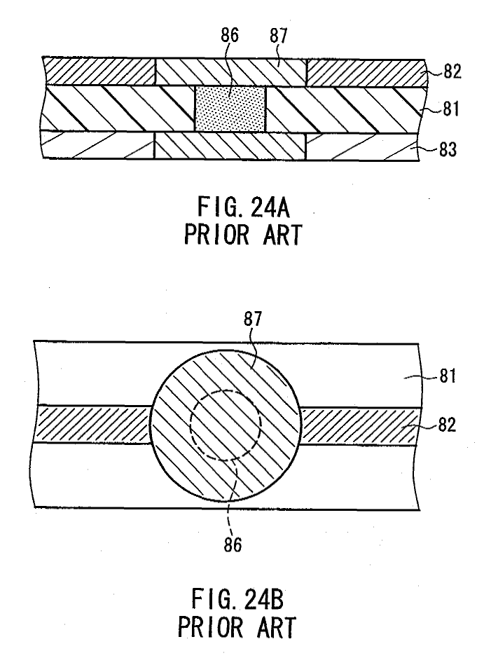

As a different comparison, a connection structure using a conventional conductive paste is shown in FIG. 24A (cross-sectional view) and FIG. 24B (top view). A through hole is opened in the thickness direction of the substrate 81, the through is filled with conductive paste 86, both sides are sandwiched by copper plates and compressed by the application of pressure and heat, after which the lands 87 remain after etching. Reference numerals 82 and 83 are conductors. Compared to the plating method, this structure has the large merits of enabling ease in making multilayer boards and achieving compactness, but there is a problem with the precision of uniformity of the upper and lower lands 87 and the land 87 must be formed larger than the vias made of portions filled with the conductive paste such that the via does not protrude from the lands 87. Therefore, it is necessary to provide extra space for the area occupied by the lands.

FIG. 18A is a cross-sectional view of a circuit board using phase change vias in another different embodiment of the present invention, and FIG, 18B is a top view of the same. To connect between the conductor layers 63 and 64, a plurality of conductive-state vias 62 are formed in the thickness direction of the phase change material layer 61, which is in an electrically insulating state, The plurality of conductive-state vias 62 connect to connect between the conductor layers 63 and 64.

For the structure of FIGS. 18A and 18B, the order may be one in which the conductor layer 63 is formed, the phase change layer is formed, the vias are formed, and then the conductor layer 64 is formed, but it is also possible to achieve this by forming the conductor layer 63, forming the phase change layer, forming the conductor layer 64, then forming the vias. This is because in the process of forming phase change vias, although phase change is caused in the phase change material of the phase change layer by the heat of laser light irradiation, conductive areas can be formed by diffusing the heat and causing phase change also in lower portions of the conductor layers 63 and 64. In this way, vias can be formed after forming the upper and lower conductor layers. Since this makes it possible to form vias after confirming the wiring pattern of the upper and lower conductor layers, it is possible to improve the precision of uniformity.

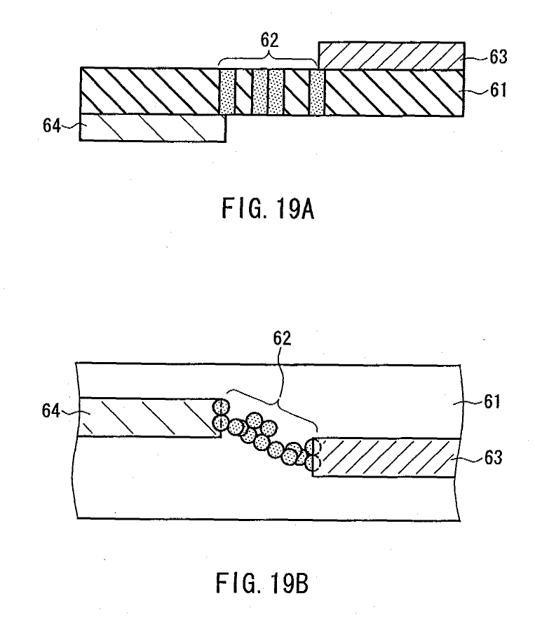

FIG. 19A is a cross-sectional view of a circuit board using phase change vias in another different embodiment of the present invention, and FIG. 19B is a top view of the same. Even if the positions of the upper and lower conductor layers 63 and 64 are displaced, it is possible to carry out the via formation process after forming the conductor layers, and therefore connection between the conductor layers 63 and 64 can be made by forming a plurality of conductive-state vias 62 in the thickness direction of the phase change material layer 61 in an electrically insulating state, after correcting for the displacement of the conductor layers 63 and 64. In this way, it is possible to reduce defects caused by conductor displacement and yields can be improved.

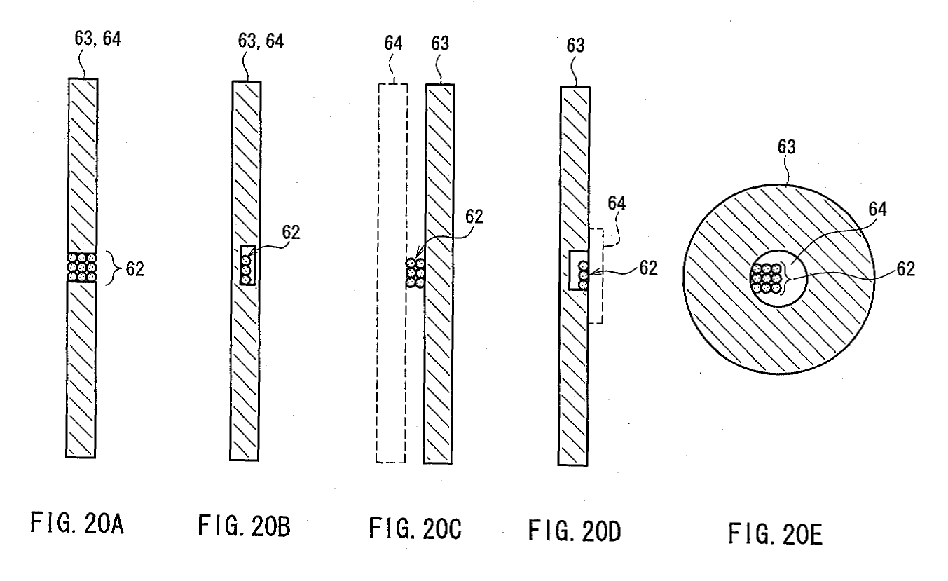

FIGS. 20A to 20E are top views of a circuit board using phase change vias in another different embodiment of the present invention. FIG. 20A shows an example in which a space is opened between the upper and the lower conductor layers 63 and 64, and a plurality of conductive-state vias 62 are formed in the thickness direction of the phase change material layer of this space. FIG. 20B shows an example in which a window portion is formed in the conductor layer 63 and the vias 62 are formed in this window portion. FIG. 20C shows an example in which, when the positions of the upper and lower conductor layers 63 and 64 are displaced, the vias 62 are formed between the conductor layers 63 and 64. FIG. 20D shows an example in which, when the conductor layers 63 and 64 are partially overlapping, a window portion is formed in the conductor layer 63, and the vias 62 are formed therein. FIG. 20E shows an example in which, when the conductor layers 63 and 64 are overlapping in concentric circle shapes, the vias 62 are formed in the overlapping portion. The above-described structures also are possible, because the phase change vias can be made wider below the conductor layers by the process in which the vias are formed.

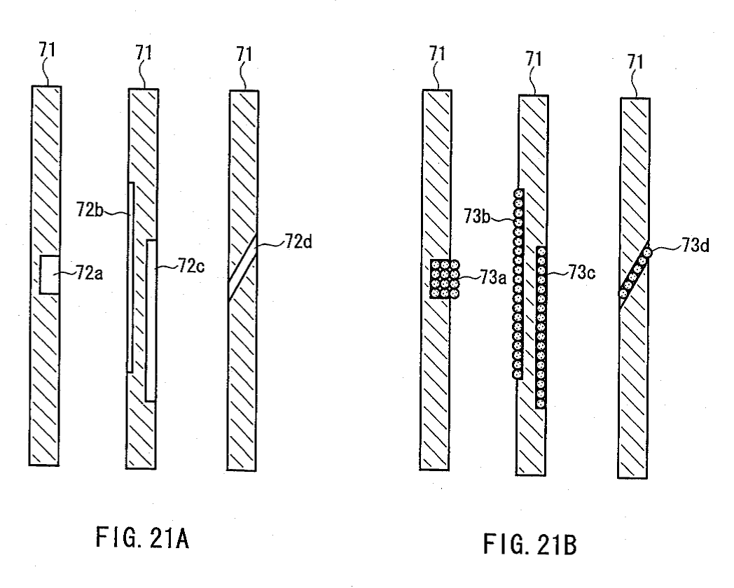

FIGS. 21A to 21B are top views showing a repair of a conductor in another different embodiment of the present invention. As shown in FIG. 21A, when forming a conductor 71 on the phase change material layer, even when a defect occurs such as those shown by reference numerals 72a to 72d, it is possible to repair and connect the conductor as shown in repair portions 73a to 73d of FIG. 21B. The above-described structure also is possible, because the phase change vias can be made wider below the conductor layers by the process in which the vias are formed.

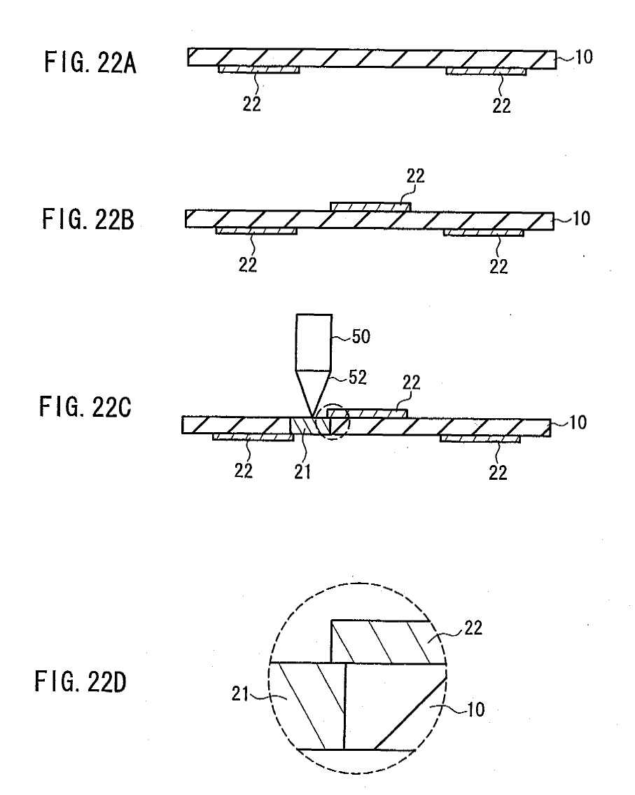

FIGS. 22A to 22D are cross-sectional views showing the steps of a different embodiment of the present invention in which the conductor layers 22 are formed (FIG. 22A) on the surface of the phase change material layer 10, and the conductor layer 22 is formed (FIG. 22B) also on the rear surface, after which the via 21 is formed by irradiating the laser light 52. The upper and lower conductors can be connected electrically by making the via formed from the phase change material wider below the conductor layers using diffusion of the beat of the laser light.

Preferred embodiments of the present invention have been described above, but these descriptions are not limitations and naturally various other modifications are possible.

The invention may be embodied in other forms without departing from the spirit or essential characteristics thereof The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1-15. (canceled)

16. A method for manufacturing a circuit board wherein, on a substrate, in at least a portion of a phase change layer comprising a phase change material that is capable of changing alternately between an electrically insulating state and an electrically conductive state, a conductive path is formed that has been put into an electrically conductive state by a phase change in the phase change layer,
wherein the phase change material comprises a chalcogenide semiconductor, changes between the electrically insulating state and the electrically conductive state by irradiation of laser light, goes into the electrically conductive state in a crystalline phase, and goes into the electrically insulating state in an amorphous phase, the method comprising the steps of:
(a) forming a phase change layer by depositing a phase change material that is capable of changing alternately between an electrically insulating state and an electrically conductive state; and
(b) forming in the phase change layer a conductive path comprising the phase change material by irradiating laser light on the phase change layer,

17. The method for manufacturing a circuit board according to claim 16, wherein the laser light in the step (b) is irradiated from a semiconductor laser.

18. The method for manufacturing a circuit board according to claim 16, wherein the laser light in the step (b) is irradiated in a state in which the phase change layer is rotatable.

19. The method for manufacturing a circuit board according to claim 16,
wherein, in the step (b), a conductor is formed as the conductive path in a surface of the phase change layer.

20. The method for manufacturing a circuit board according to claim 16,
wherein, in the step (b), a via is formed inside the phase change layer.

21. The method for manufacturing a circuit board according to claim 16,
wherein, in the step (b), a conductor is formed as the conductive path in a surface of the phase change layer and a via is formed as the conductive path extending from a portion of the conductor.

22. The method for manufacturing a circuit board according to claim 16,
wherein the substrate is a circuit board on which a conductor layer is formed on at least a surface or is a temporary substrate that is later removed.

23. The method for manufacturing a circuit board according to claim 16,
wherein, when a metal conductor is formed on a surface of the substrate and the surface is uneven, the phase change material is flattened after the phase change material layer is formed.

24. The method for manufacturing a circuit board according to claim 16,
wherein a further phase change layer is formed on the phase change layer, and the conductive path is formed also on the further phase change layer.

25. The method for manufacturing a circuit board according to claim 16,
wherein a via is formed as the conductive path in the phase change layer, and a metal conductor is connected to the via at a surface of the phase change layer.

26. The method for manufacturing a circuit board according to claim 25,
wherein a second phase change layer is formed on the metal conductor, and a via that is a conductive path is formed in the second phase change layer.

27. The method for manufacturing a circuit board according to claim 26,
wherein, when forming the second phase change layer, the second phase change material layer is formed so as to cover a conductor comprising metal, and thereafter the phase change material is flattened.

28. The method for manufacturing a circuit board according to claim 16,
wherein a conductive path comprising the phase change material is formed inside the phase change layer by focusing the irradiated laser light inside the phase change layer.

29. The method for manufacturing a circuit board according to claim 16,
wherein, when forming the conductive path, a plurality of electrodes are formed in advance, and a conductive path comprising the phase change material is formed in the phase change layer by irradiating the laser light from a semiconductor laser to the phase change layer, while measuring an electrical property between the electrodes, in such a manner that a predetermined electrical property is obtained.

30. The method for manufacturing a circuit board according to claim 16,
wherein, after a conductor layer is formed on both sides of the phase change material layer, a via is formed by irradiating laser light, and an upper conductor and a lower conductor are electrically connected by making the via wider until reaching below the conductors using diffusion of the heat of the laser light.
